(19) United States
(12) Patent Application Publication
(10) Pub. No.: US 2016/0180898 A1
(43) Pub. Date: Jun. 23, 2016

(54) MEMORY CONTROLLER AND MEMORY SYSTEM INCLUDING THE SAME

(71) Applicant: SAMSUNG ELECTRONICS CO., LTD., SUWON-SI (KR)

(72) Inventors: SOON SUK HWANG, ANSAN-SI (KR); KYU WOOK HAN, SEOUL (KR)

(21) Appl. No.: 14/959,106

(22) Filed: Dec. 4, 2015

(30) Foreign Application Priority Data
Dec. 19, 2014 (KR) 10-2014-0184630

(51) Int. Cl. G11C 7/10; G06F 12/02; G11C 16/26

(52) U.S. Cl. CPC G11C 7/1063; G11C 7/106; G11C 16/26; G06F 12/0246; G06F 2212/7201

(57) ABSTRACT

A memory controller for controlling a flash memory device is provided. The memory controller generates pattern data, a program command, and a read command, transmits the program command and first data corresponding to the pattern data to the flash memory device so that the first data is programmed to the flash memory device, receives first read data corresponding to the first data, receives a first read data strobe signal, compares the first data with second data corresponding to the first read data, and performs a data training operation according to a comparison result. The first read data and the first read strobe signal are transmitted from the flash memory device in response to the read command.

### CROSS-REFERENCE TO RELATED APPLICATION

This application claims priority under 35 U.S.C. §119(a) to Korean Patent Application No. 10-2014-0184630, filed on Dec. 19, 2014, in the Korean Intellectual Property Office, the disclosure of which is incorporated by reference herein in its entirety.

### TECHNICAL FIELD

Exemplary embodiments of the present inventive concept relate to a memory controller, and more particularly, to a memory controller for compensating for skew between signals and a memory system including the memory controller.

### DISCUSSION OF THE RELATED ART

A flash memory device is a non-volatile memory device that retains information even when not powered.

As a data transmission rate increases in the flash memory device, skew (e.g., a phase difference between signals) may occur among various signals in the flash memory device or between the flash memory device and another device, and thus, a technique for compensating for skew may be employed.

### SUMMARY

According to an exemplary embodiment of the present inventive concept, a memory controller for controlling a flash memory device is provided. The memory controller generates pattern data, a program command, and a read command, and transmits the program command and first data corresponding to the pattern data to the flash memory device to program the first data to the flash memory device. The memory controller further receives first read data corresponding to the first data, receives a first read data strobe signal, compares the first data with second data corresponding to the first read data, and performs a data training operation according to a comparison result. The first read data and the first read strobe signal are transmitted from the flash memory device in response to the read command.

The memory controller may include a phase shift block and a latch block. The phase shift block may be configured to shift a phase of the first read data strobe signal when the data training operation is a read training operation. The latch block may be configured to latch the first read data in response to the first read data strobe signal whose phase has been shifted by the phase shift block, and to output the latched first read data as the second data.

The memory controller may further include a comparator configured to compare the first data with the second data, and to output a pass signal of the read training operation when the first data is the same as the second data.

The memory controller may further include a comparator and a processing unit. The comparator may be configured to compare the first data with the second data and to output a fail signal of the read training operation when the first data is not the same as the second data. The processing unit may be configured to retransmit the read command to the flash memory device in response to the fail signal. The phase shift block may receive a second read data strobe signal from the flash memory device. The latch block may receive second read data from a page buffer of the flash memory device.

The first data may be transmitted to the flash memory device in synchronization with a clock signal having a first frequency. The first read data may be received from the flash memory device in synchronization with the first read data strobe signal having a second frequency. The first frequency may be lower than the second frequency.

The first read data strobe signal may be generated by the flash memory device.

The memory controller may include a phase shift block and a latch block. The phase shift block may be configured to first shift a phase of a clock signal when the data training operation is a write training operation. The latch block may be configured to first latch the pattern data in response to the clock signal whose phase has been shifted by the phase shift block, and to output the first latched pattern data as the first data.

The memory controller may further include a comparator configured to compare the first data with the second data, and to output a pass signal of the write training operation when the first data is the same as the second data.

The memory controller may further include a comparator configured to compare the first data with the second data, and to output a fail signal of the write training operation when the first data is not the same as the second data. The phase shift block may second shift the phase of the clock signal in response to the fail signal. The latch block may second latch the pattern data in response to the clock signal whose phase has been second shifted by the phase shift block and outputs the second latched pattern data as the first data.

According to an exemplary embodiment of the present inventive concept, a memory system is provided. The memory system includes a flash memory device and a memory controller. The memory controller is configured to control a data training operation of the flash memory device. The memory controller generates pattern data, a program command, a read command, and transmits the program command and first data corresponding to the pattern data to the flash memory device to program the first data to the flash memory device. The memory controller further receives first read data corresponding to the first data, receives a first read data strobe signal, compares the first data with second data corresponding to the first read data, and performs the data training operation according to a comparison result. The first read data and the first read strobe signal are transmitted from the flash memory device in response to the read command.

The memory controller may include a phase shift block and a latch block. The phase shift block may be configured to shift a phase of the first read data strobe signal when the data training operation is a read training operation. The latch block may be configured to latch the first read data in response to the first read data strobe signal whose phase has been shifted by the phase shift block, and to output the latched first read data as the second data.

The memory controller may further include a comparator and a processing unit. The comparator may be configured to compare the first data with the second data, and to output a fail signal of the read training operation when the first data is not the same as the second data. The processing unit may be configured to retransmit the read command to the flash memory device in response to the fail signal. The phase shift block may receive a second read data strobe signal from the flash memory device. The latch block may receive second read data from a page buffer of the flash memory device.

The first data may be transmitted to the flash memory device in synchronization with a clock signal having a first frequency. The first read data may be received from the flash memory device in synchronization with the first read data strobe signal having a second frequency. The first frequency may be lower than the second frequency.

The memory controller may include a phase shift block and a latch block. The phase shift block may be configured to first shift a phase of a clock signal when the data training operation is a write training operation. The latch block may be configured to first latch the pattern data in response to the clock signal whose phase has been first shifted by the phase shift block, and to output the first latched pattern data as the first data.

The memory controller may further include a comparator configured to compare the first data with the second data, and to output a fail signal of the write training operation when the first data is not the same as the second data. The phase shift block may second shift the phase of the clock signal in response to the fail signal. The latch block may second latch the pattern data in response to the clock signal whose phase has been second shifted by the phase shift block and may output the second latched pattern data as the first data.

According to an exemplary embodiment of the present inventive concept, a method of operating a memory system is provided. The method includes generating, by a memory controller of the memory system, first data, a program command, and a read command, transmitting, by the memory controller, the first data and the program command to a flash memory device of the memory system, programming, by the flash memory device, the first data to a page buffer of the flash memory device in response to the program command, transmitting, by the memory controller, the read command to the flash memory device, receiving, by the memory controller, a first read data and a first read strobe signal, generating, by the memory controller, second data by latching the first read data, and comparing, by the memory controller, the first data with the second data.

The method may further include shifting a phase of the first read data strobe signal when the memory controller is in a read training operation. The latching of the first read data may be performed in response to the first read data strobe signal whose phase has been shifted.

The method may further include determining, by the memory controller, the read training operation to have passed when the first data is the same as the second data.

The method may further include determining, by the memory controller, the read training operation to have failed when the first data is not the same as the second data.

The first data may be transmitted to the flash memory device in synchronization with a clock signal having a first frequency. The first read data may be received from the flash memory device in synchronization with the first read data strobe signal having a second frequency. The first frequency may be lower than the second frequency.

### BRIEF DESCRIPTION OF THE DRAWINGS

The above and other features of the present inventive concept will become more apparent by describing in detail exemplary embodiments thereof with reference to the attached drawings in which:

FIG. 1 is a block diagram of a data processing system according to an exemplary embodiment of the present inventive concept;

FIG. 2 is a block diagram of a flash memory device illustrated in FIG. 1 according to an exemplary embodiment of the present inventive concept;

FIG. 3 is a block diagram of a skew compensation block of FIG. 1 according to an exemplary embodiment of the present inventive concept;

FIG. 4 is a flowchart illustrating an operation of a memory system including the skew compensation block illustrated in FIG. 3 according to an exemplary embodiment of the present inventive concept;

FIG. 5 is a diagram illustrating an operation of a memory controller which determines whether a read training operation has passed or failed according to an amount of phase shift of a read data strobe signal according to an exemplary embodiment of the present inventive concept;

FIG. 6 is a diagram illustrating a per-pin data training according to an exemplary embodiment of the present inventive concept;

FIG. 7 is a block diagram of the skew compensation block illustrated in FIG. 1 according to an exemplary embodiment of the present inventive concept;

FIG. 8 is a flowchart illustrating an operation of a memory system including the skew compensation block illustrated in FIG. 7 according to an exemplary embodiment of the present inventive concept;

FIG. 9 is a diagram illustrating an operation of a memory controller which determines whether a write training operation has passed or failed according to a phase shift of a clock signal according to an exemplary embodiment of the present inventive concept;

FIG. 10 is a block diagram of a data processing system according to an exemplary embodiments of the present inventive concept;

FIG. 11 is a block diagram of a data processing system according to an exemplary embodiments of the present inventive concept;

FIG. 12 is a block diagram of a data processing system according to an exemplary embodiments of the present inventive concept; and

FIG. 13 is a block diagram of a data processing system according to an exemplary embodiment of the present inventive concept.

### DETAILED DESCRIPTION OF THE EMBODIMENTS

Exemplary embodiments of the present inventive concept will now be described more fully hereinafter with reference to the accompanying drawings. The present inventive concept may, however, be embodied in many different forms and should not be construed as limited to the embodiments set forth herein. In the drawings, the size and relative sizes of layers and regions may be exaggerated for clarity. Like numbers may refer to like elements throughout the specification and drawings. All the elements throughout the specification and drawings may be circuits.

It will be understood that when an element is referred to as being “connected” or “coupled” to another element, it can be directly connected or coupled to the other element or intervening elements may be present.

As used herein, the singular forms “a”, “an” and “the” are intended to include the plural forms as well, unless the context clearly indicates otherwise.

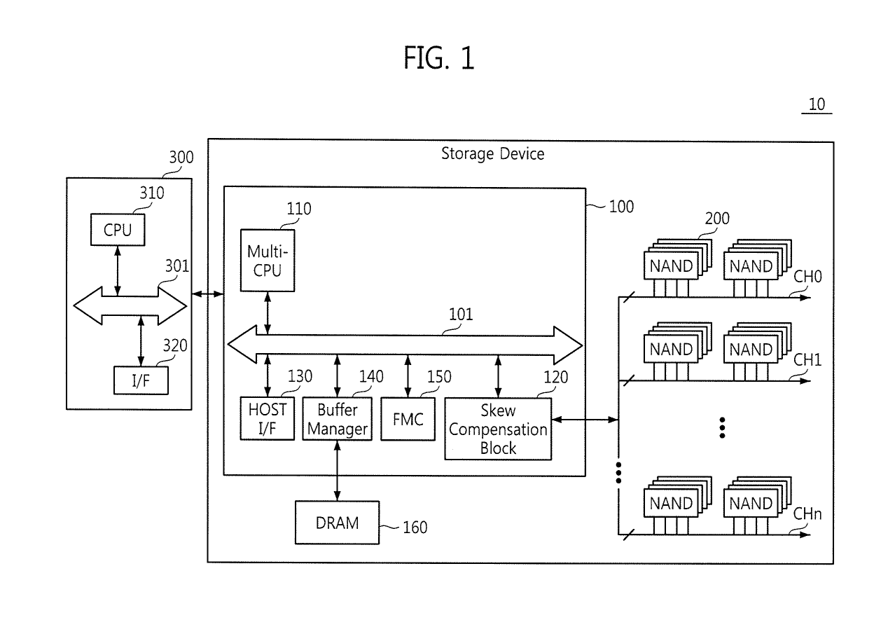

FIG. 1 is a block diagram of a data processing system 10 according to an exemplary embodiment of the present inventive concept. The data processing system 10 includes a memory controller 100, a flash memory device 200, and a host 300. A storage device, which may be a memory system, may include the memory controller 100 and the flash memory device 200. The storage device may be implemented as a solid state drive (SSD), an embedded SSD (eSSD), or the like. The data processing system 10 may be implemented as a personal computer (PC) or a portable electronic device, such as a laptop computer, a cellular phone, a smart phone, a tablet PC, a personal digital assistant (PDA), an enterprise digital assistant (EDA), a digital still camera, a digital video camera, a portable multimedia player (PMP), a personal navigation device, a portable navigation device (PND), a handheld game console, a mobile internet device (MID), a wearable computer, an internet of things (IoT) device, an internet of everything (IoE) device, an e-book, or the like.

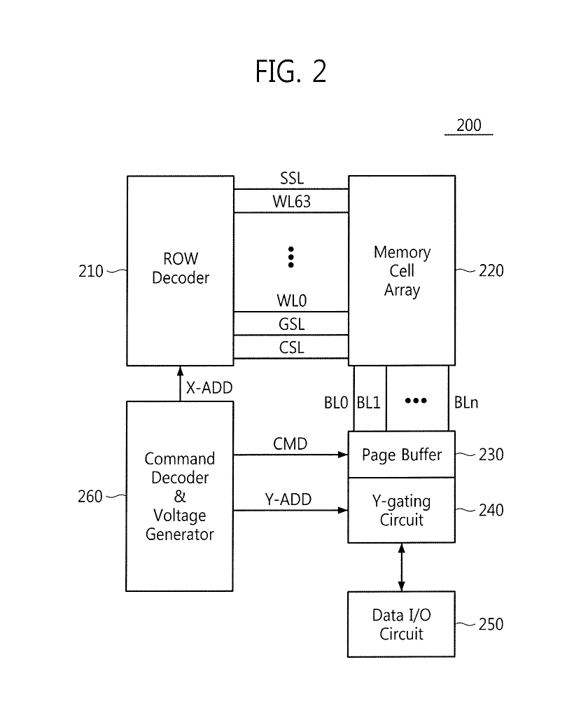

The memory controller 100 may include a multi-central processing unit (CPU) 110, a skew compensation block 120, a host interface (I/F) 130, a buffer manager 140, and a flash memory controller (FMC) 150. The memory controller 100 may control data processing operations, such as a program operation, a read operation, an erase operation, or the like, of the flash memory device 200 according to the control of the host 300. The memory controller 100 may control a data training operation of the flash memory device 200 which includes a page buffer (e.g., 230 in FIG. 2). The data training operation may be an operation of compensating for skew that may occur during data transmission between the memory controller 100 and the flash memory device 200.

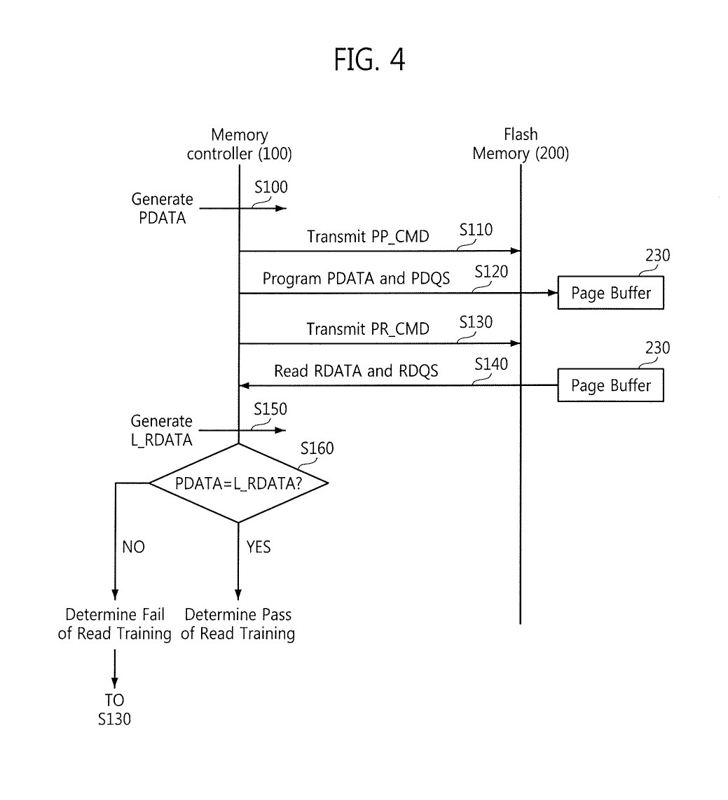

The multi-CPU 110 may control the skew compensation block 120, the host I/F 130, the buffer manager 140, and the FMC 150. The multi-CPU 110 may generate a program command (e.g., PP_CMD in FIG. 4) to program first data to a page buffer (e.g., 230 in FIG. 2) and a read command (e.g., PR_CMD in FIG. 4) to read second data from the page buffer. The page buffer may be included in the flash memory device 200.

The skew compensation block 120 may compensate for skew that may occur during data transmission between the memory controller 100 and the flash memory device 200 according to the control of the multi-CPU 110. The host I/F 130 may transmit data that has been processed by the memory controller 100 to the host 300 and may receive data that has been processed by the host 300.

The buffer manager 140 may control data transferred between the memory controller 100 and the host 300 to be stored in dynamic random access memory (DRAM) 160. The FMC 150 may control the flash memory device 200 including a plurality of memory cells according to the control of the multi-CPU 110.

The flash memory device 200 may include a plurality of memory cells, each of which may be a single level cell (SLC) for storing data of a single bit, a multi-level cell (MLC) for storing data of at least two bits, a triple level cell (TLC) for storing data of at least three bits, or the like. The flash memory device 200 may be implemented as a smart card, a secure digital (SD) card, a micro SD card, a multimedia card (MMC), an embedded MMC (eMMC), an embedded multi-chip package (eMCP), a perfect page NAND (PPN), a universal flash storage (UFS), or the like.

The host 300 may include a CPU 310 and an I/FF 320. The host 300 may be implemented as an integrated circuit (IC), a system on chip (SoC), an application processor (AP), a mobile AP, or the like. The host 300 may communicate data with the memory controller 100 through the I/F 320 according to the control of the CPU 310.

FIG. 2 is a block diagram of a flash memory device 200 illustrated in FIG. 1 according to an exemplary embodiment of the present inventive concept. Referring to FIG. 2, the flash memory device 200 may include a row decoder 210, a memory cell array 220, a page buffer block 230, a Y-gating circuit 240, a data input/output (I/O) circuit 250, and a command decoder and voltage generator 260.

The row decoder 210 may be connected with the memory cell array 220 through a plurality of word lines WL0 through WL63. The row decoder 210 may select one of the word lines WL0 through WL63 based on a control signal X-ADD output from the command decoder and voltage generator 260.

The memory cell array 220 may include a plurality of memory cells, each of which is connected with one of the word lines WL0 through WL63 and one of bit lines BL0 through BLn (where “n” is a natural number). The memory cell array 220 may include a plurality of cell strings. Each of the cell strings may include a string selection transistor connected to a string selection line SSL, a plurality of memory cells respectively connected to the word lines WL0 through WL63, and a ground selection transistor connected to a ground selection line GSL. The string selection transistor may be connected to one of the bit lines BL0 through BLn, and the ground selection transistor may be connected to a common source line CSL.

In an exemplary embodiment of the present inventive concept, the memory cell array 220 may include a two dimensional (2D) memory array or a three dimensional (3D) memory array. The 3D memory array is monolithically formed as one or more physical levels in arrays of memory cells having an active area which is disposed above a silicon substrate and circuitry. Here, the circuitry may be associated with the operation of the memory cells and may be disposed above the silicon substrate or in the silicon substrate. The term “monolithic” may be understood to mean that layers of each physical level of the array are directly deposited on the layers of each underlying level of the array.

In an exemplary embodiment of the present inventive concept, the 3D memory array includes vertical NAND strings that are vertically oriented such that at least one memory cell is disposed above another memory cell. The at least one memory cell may include a charge trap layer.

The following patent documents, U.S. Pat. No. 7,679,133, U.S. Pat. No. 8,553,466, U.S. Pat. No. 8,654,587, U.S. Pat. No. 8,559,235, and U.S. Patent Publication Number 2011/0233648, describe exemplary configurations for 3D memory arrays, in which the 3D memory array is formed as a plurality of levels with word lines and/or bit lines shared between the levels. The aforementioned documents are herein incorporated by reference in their entireties.

The page buffer block 230 may include a plurality of page buffers, each of which is connected with each of the bit lines BL0 through BLn. The page buffer block 230 may operate as a driver that programs data to the memory cell array 220 during a program operation of the flash memory device 200. In addition, the page buffer block 230 may operate as a sense amplifier that senses and amplifies a voltage level of each of the bit lines BL0 through BLn during a read operation of the flash memory device 200.

The page buffer block 230 may receive data, which would be programmed to, e.g., the memory cell array 220, from the memory controller 100. The page buffer block 230 may store data which would be programmed to memory cell or data which has been read from a selected memory cell of the memory cell array 220. The Y-gating circuit 240 may control data transmission between the page buffer block 230 and the data I/O block 250 based on a control signal Y-ADD output from the command decoder and voltage generator 260.

The data I/O block 250 may transmit data from the memory controller 100 to the Y-gating circuit 240 or may transmit data from the Y-gating circuit 240 to the memory controller 100 through a plurality of I/O pins or a data bus. The data I/O block 250 may receive data from an external device. The data I/O block 250 may temporarily store data that would be programmed to a selected memory cell among the memory cells.

The data stored in the data I/O block 250 may be programmed to the selected memory cell during a program operation. The data I/O block 250 may read data from selected memory cells through the bit lines BL0 through BLn and may output the read data to an external device.

The command decoder and voltage generator 260 may receive and decode a command signal, may generate, a command, an address, or both of the command and the address to control the components 210, 220, 230, and 240 according to the decoding result, and may generate voltages (e.g., a program voltage, a pass voltage, and a read voltage) which are necessary for the operation of the flash memory device 200.

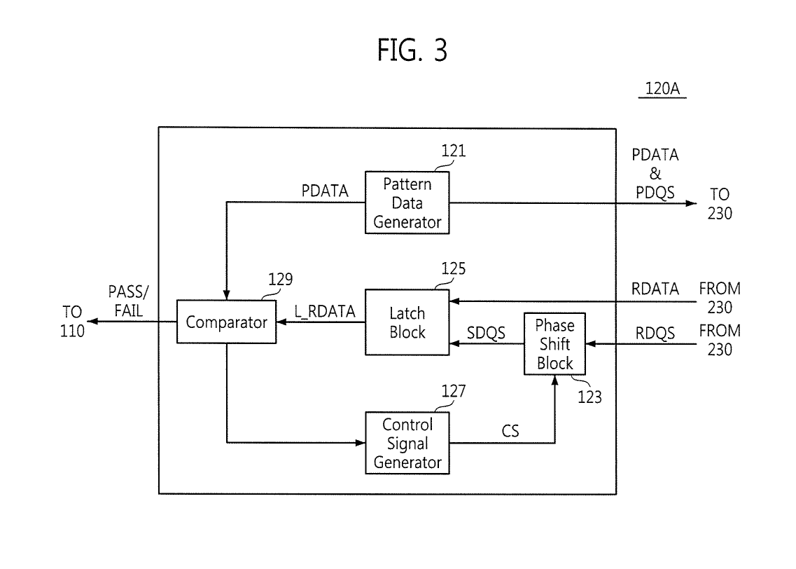

FIG. 3 is a block diagram of an example 120A of a skew compensation block 120 illustrated in FIG. 1 according to an exemplary embodiment of the present inventive concept. FIG. 4 is a flowchart illustrating an operation of a memory system including the skew compensation block 120A illustrated in FIG. 3 according to an exemplary embodiment of the present inventive concept. Referring to FIG. 3, the skew compensation block 120A may include a pattern data generator 121, a phase shift block 123, a latch block 125, a control signal generator 127, and a comparator 129. The skew compensation block 120A may compensate for skew that may occur in the flash memory device 200 by performing a read training operation.

Referring to FIGS. 1 through 4, the pattern data generator 121 of the memory controller 100 may generate pattern data PDATA according to the control of the multi-CPU 110 in operation S100. The memory controller 100 may generate a program command PP_CMD and transmit the program command PP_CMD to the flash memory device 200 in operation S110. At this time, the program command PP_CMD may be a signal which commands to the pattern data PDATA to be programmed to the page buffer 230 of the flash memory device 200, or a signal which commands the pattern data PDATA not to be programmed to the memory cell array 220. The program command PP_CMD may be generated by the multi-CPU 110 or the FMC 150.

The memory controller 100 may transmit the pattern data PDATA to the flash memory device 200, and thus, the pattern data PDATA is programmed to the page buffer 230 in the flash memory device 200. The memory controller 100 may program the pattern data PDATA and a pattern data strobe signal PDQS to the page buffer 230 in response to the program command PP_CMD in operation S120. For example, the pattern data generator 121 may program the pattern data PDATA and the pattern data strobe signal PDQS to the page buffer 230.

The memory controller 100 may generate a read command PR_CMD and transmit the read command PR_CMD to the flash memory device 200 in operation S130. At this time, the read command PR_CMD may be a signal which commands to read data RDATA to be read from the page buffer 230, or a signal which commands the read data RDATA not to be read from the memory cell array 220. The read command PR_CMD may be generated by the multi-CPU 110 or the FMC 150.

The memory controller 100 reads the read data RDATA and a read data strobe signal RDQS output from the page buffer 230, determines whether skew has occurred between data (e.g., the read data RDATA and the read data strobe signal RDQS), and performs the read training operation to compensate for the skew. In this case, the read data RDATA and the read data strobe signal RDQS may correspond to the pattern data PDATA and the pattern data strobe signal PDQS, respectively, which have been programmed to the page buffer 230. The read data strobe signal RDQS may be generated by the flash memory device 200.

The memory controller 100 may read the read data RDATA and the read data strobe signal RDQS which have been transmitted from the page buffer 230 in response to the read command PR_CMD in operation S140. For example, the latch block 125 may read the read data RDATA transmitted from the page buffer 230, and the phase shift block 123 may read the read data strobe signal RDQS transmitted from the page buffer 230. For example, reading data may be understood as receiving the data from a particular device.

The pattern data PDATA may be transmitted to the flash memory device 200 in synchronization with a clock signal having a first frequency. The read data RDATA may be received from the flash memory device 200 in synchronization with the read data strobe signal RDQS having a second frequency. The first frequency may be lower than the second frequency.

The phase shift block 123 may shift a phase of the read data strobe signal RDQS, which has been transmitted from the page buffer 230, based on a control signal CS generated by the control signal generator 127, and thus, a read data strobe signal SDQS having the shifted phase may be generated. The latch block 125 may receive the read data RDATA from the page buffer 230, and may receive the read data strobe signal SDQS having the shifted phase from the phase shift block 123, and may process the read data RDATA and the read data strobe signal SDQS having the shifted phase, and thus, latched read data L_RDATA may be generated in operation S150. The latched read data L_RDATA may be generated by latching the read data RDATA according to an amount of phase shift of the read data strobe signal RDQS. The latch block 125 may be implemented as a flip-flop.

The control signal generator 127 may control an amount of the phase shift of the read data strobe signal RDQS by the phase shift block 123. The comparator 129 may determine the read training operation on the flash memory device 200 to have passed or failed according to whether the pattern data PDATA output from the pattern data generator 121 is the same as the latched read data L_RDATA from the latch block 125 in operation S160. For example, when the pattern data PDATA is the same as the latched read data L_RDATA, the comparator 129 may send a pass signal PASS to the multi-CPU 110. In an exemplary embodiment of the present inventive concept, the comparator 129 may send the pass signal PASS to the FMC 150. The pass signal PASS may indicate that the read training operation on the flash memory device 200 has been successful.

When the pattern data PDATA is not the same as the latched read data L_RDATA, the comparator 129 may send a fail signal FAIL to the multi-CPU 110. In an exemplary embodiment of the present inventive concept, the comparator 129 may send the fail signal FAIL to the FMC 150. The fail signal FAIL may indicate that the read training operation on the flash memory device 200 has failed.

When the pattern data PDATA is the same as the latched read data L_RDATA, the memory controller 100 may determine that the read training operation has passed and may detect a data valid window by repeating the read training operation. When the pattern data PDATA is not the same as the latched read data L_RDATA, the memory controller 100 may determine that the read training operation has failed and restart the read training operation in operation S130.

For example, when the pattern data PDATA is not the same as the latched read data L_RDATA, the comparator 129 may output the fail signal FAIL with respect to the read training operation and the multi-CPU 110 may retransmit the read command PR_CMD to the flash memory device 200 in response to the fail signal FAIL. The phase shift block 123 may newly receive the read data strobe signal RDQS from the flash memory device 200 and the latch block 125 may newly receive the read data RDATA from the page buffer 230.

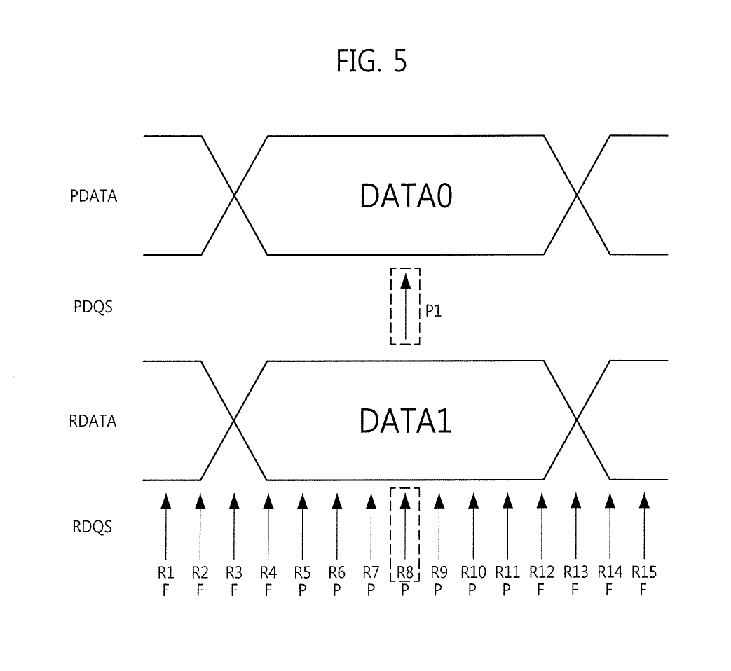

FIG. 5 is a diagram of an operation of a memory controller 100 which determines whether a read training operation has passed or failed according to an amount of phase shift of a read data strobe signal RDQS according to an exemplary embodiment of the present inventive concept. Referring to FIGS. 1 through 5, the pattern data generator 121 may generate the pattern data PDATA and the pattern data strobe signal PDQS. The pattern data strobe signal PDQS may have a rising or falling edge at the middle point (e.g., P1) of the pattern data PDATA.

The phase shift block 123 may receive the read data strobe signal RDQS from the page buffer 230, and may shift the phase of the read data strobe signal RDQS. At this time, the phase of the read data strobe signal RDQS may be shifted in response to the control signal CS received from the control signal generator 127. The phase of the read data strobe signal RDQS may be shifted such that the read data strobe signal RDQS has a rising or falling edge at one of time points R1 through R15.

The read data RDATA may be latched according to the read data strobe signal RDQS having a phase shift such that the read data strobe signal RDQS has a rising or falling edge at one of the time points R1 through R15. The comparator 129 may determine the read training operation to have passed or failed according to whether the latched read data L_RDATA is the same as the pattern data PDATA.

Referring to FIG. 5, when the pattern data PDATA has a value of DATA0 at a rising or falling edge of the pattern data strobe signal PDQS, and the read data RDATA has a value of DATA1 at a rising or falling edge of the read data strobe signal RDQS whose phase has been shifted, the latched read data L_RDATA is the same as the pattern data PDATA. For example, when the read data strobe signal RDQS has a phase shift to have a rising or falling edge at one of time points R1 through R4, the latched read data L_RDATA is not the same as the pattern data PDATA, and the memory controller 100 may determine the read training operation to have failed. When the read data strobe signal RDQS has a phase to have a rising or falling edge at one of time points R5 through R11, the latched read data L_RDATA is the same as the pattern data PDATA, and the memory controller 100 may determine the read training operation to have passed. When the read data strobe signal RDQS has a phase to have a rising or falling edge at one of time points R12 through R15, the latched read data L_RDATA is not the same as the pattern data PDATA, and the memory controller 100 may determine the read training operation to have failed.

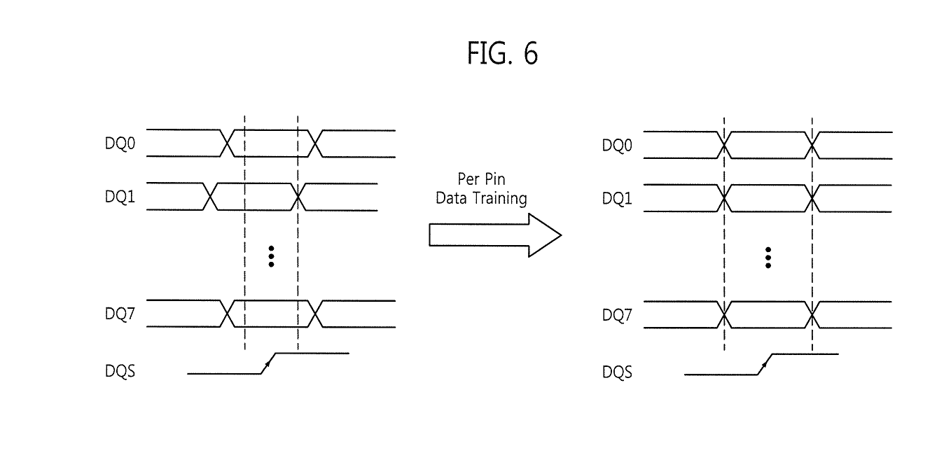

FIG. 6 is a diagram of a per-pin data training according to an exemplary embodiment of the present inventive concept. The memory controller 100 may compensate for data skew that may occur among data lines DQ0 through DQ7 by performing a read training operation described with reference to FIG. 5 on each data of the data lines DQ0 through DQ7 in a sequential or parallel manner.

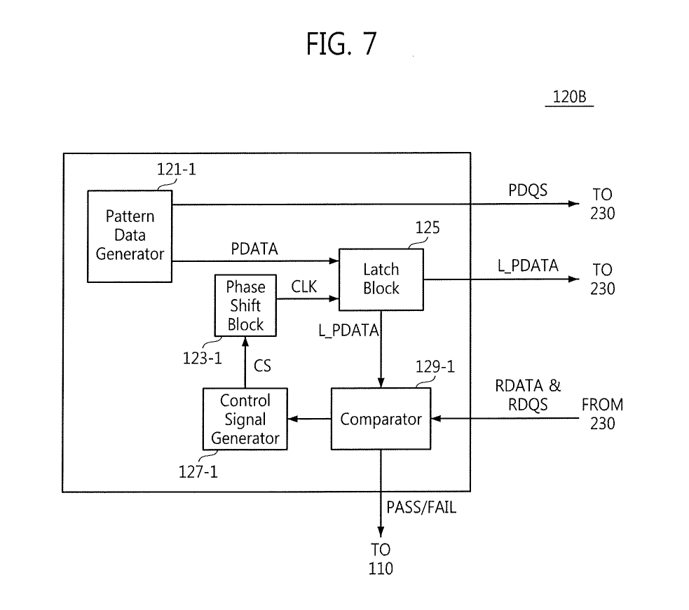

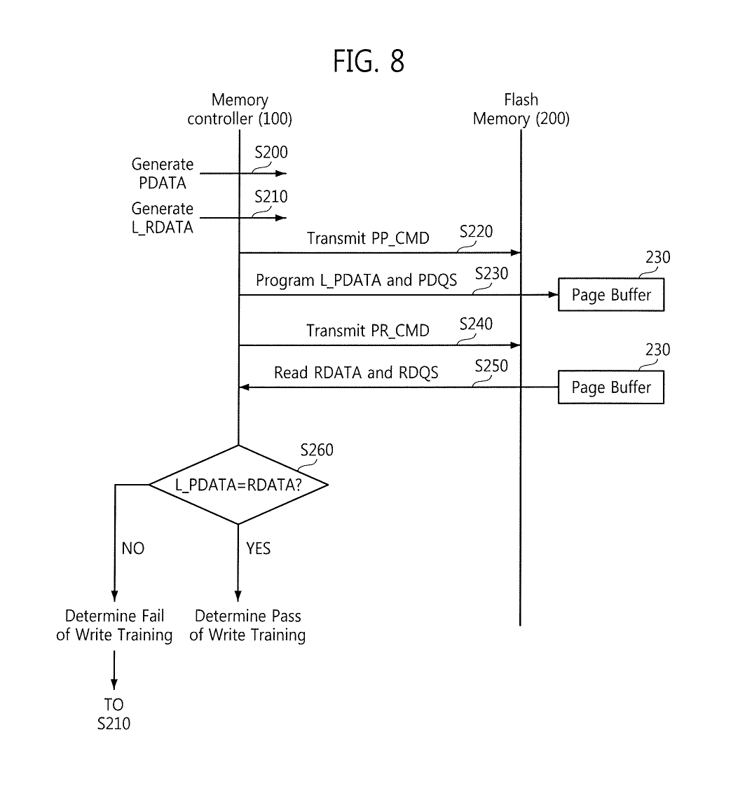

FIG. 7 is a block diagram of an example 120B of the skew compensation block 120 illustrated in FIG. 1 according to an exemplary embodiment of the present inventive concept. FIG. 8 is a flowchart illustrating an operation of a memory system including the skew compensation block 120B illustrated in FIG. 7 according to an exemplary embodiment of the present inventive concept. Referring to FIG. 7, the skew compensation block 120B may include a pattern data generator 121-1, a phase shift block 123-1, a latch block 125-1, a control signal generator 127-1, and a comparator 129-1. The skew compensation block 120B may compensate for skew that may occur in the flash memory device 200 by performing a write training operation.

Referring to FIGS. 1 through 8, the pattern data generator 121-1 may generate the pattern data PDATA according to the control of the multi-CPU 110 in operation S200. The pattern data generator 121-1 may generate the pattern data strobe signal PDQS corresponding to the pattern data PDATA. The phase shift block 123-1 may shift the phase of a clock signal based on the control signal CS generated by the control signal generator 127-1.

The latch block 125-1 may receive the pattern data PDATA from the pattern data generator 121-1 and a clock signal CLK having a phase shifted by the phase shift block 123-1 and may process the pattern data PDATA and the clock signal CLK to generate latched pattern data L_PDATA in operation S210. The latch block 125-1 may be implemented as a flip-flop. The latched pattern data L_PDATA may be generated by latching the pattern data PDATA according to the clock signal CLK whose phase has been shifted by the phase shift block 123-1.

The memory controller 100 may generate the program command PP_CMD and transmit the program command PP_CMD to the flash memory device 200 in operation S220.

At this time, the program command PP_CMD may be a signal which commands to the latched pattern data L_PDATA to be programmed to the page buffer 230, or a signal which commands the latched pattern data L_PDATA not to be programmed to the memory cell array 220. The program command PP_CMD may be generated by the multi-CPU 110 or the FMC 150.

The memory controller 100 may transmit the latched pattern data L_PDATA to the flash memory device 200, and thus, the latched pattern data L_PDATA is programmed to the page buffer 230 in the flash memory device 200. The memory controller 100 may program the latched pattern data L_PDATA and the pattern data strobe signal PDQS to the page buffer 230 in response to the program command PP_CMD in operation S230.

The memory controller 100 may generate the read command PR_CMD and transmit the read command PR_CMD to the flash memory device 200 in operation S240. At this time, the read command PR_CMD may be a signal which commands the read data RDATA to be read from the page buffer 230, or a signal which commands the read data RDATA not to be read from the memory cell array 220. The read command PR_CMD may be generated by the multi-CPU 110 or the FMC 150.

The memory controller 100 may read the read data RDATA and the read data strobe signal RDQS which have been transmitted from the page buffer 230 in response to the read command PR_CMD in operation S250. For example, the comparator 129-1 may read the read data RDATA and the read data strobe signal RDQS from the page buffer 230. The read data strobe signal RDQS may be generated in the flash memory device 200.

The comparator 129-1 may determine the write training operation on the flash memory device 200 to have passed or failed according to whether the latched pattern data L_PDATA generated by the latch block 125-1 is the same as the read data RDATA transmitted from the page buffer 230 in operation S260. When the latched pattern data L_PDATA is the same as the read data RDATA, the comparator 129-1 may send a pass signal PASS to the multi-CPU 110. In an exemplary embodiment of the present inventive concept, the comparator 129-1 may send the pass signal PASS to the FMC 150. The pass signal PASS may indicate that the write training operation on the flash memory device 200 has been successful.

When the latched pattern data L_PDATA is not the same as the read data RDATA, the comparator 129 may send a fail signal FAIL to the multi-CPU 110. In an exemplary embodiment of the present inventive concept, the comparator 129 may send the fail signal FAIL to the FMC 150. The fail signal FAIL may indicate that the write training operation on the flash memory device 200 has failed.

When the latched pattern data L_PDATA is the same as the read data RDATA, the memory controller 100 may determine that the write training operation has passed and may detect a data valid window by repeating the write training operation. When the latched pattern data L_PDATA is not the same as the read data RDATA, the memory controller 100 may determine that the write training operation has failed and restart the write training operation in operation S210. For example, when the latched pattern data L_PDATA is not the same as the read data RDATA, the memory controller 100 may transmit the fail signal FAIL to the multi-CPU 110. The phase shift block 123-1 may newly shift the phase of the clock signal in response to the fail signal FAIL. The latch block 125-1 may latch the pattern data PDATA according to the clock signal CLK having the newly shifted phase and may output the newly latched pattern data L_PDATA.

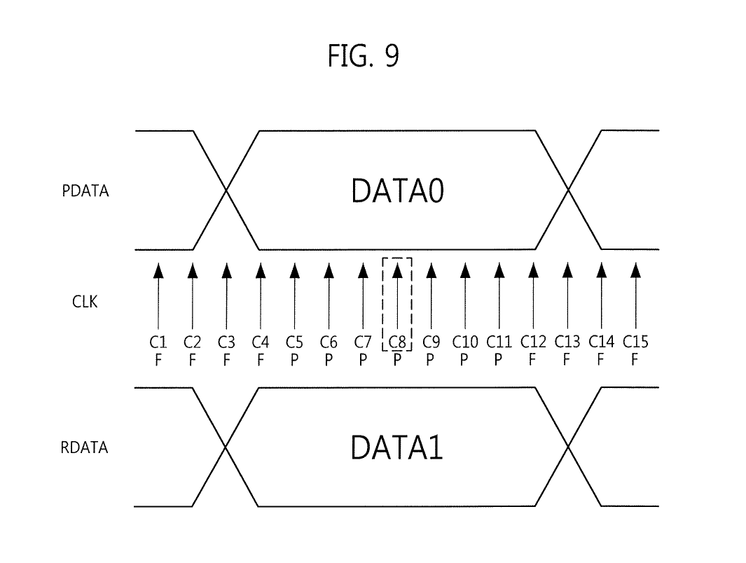

FIG. 9 is a diagram illustrating an operation of a memory controller 100 which determines whether a write training operation has passed or failed according to an amount of phase shift of a clock signal CLK according to an exemplary embodiment of the present inventive concept. Referring to FIGS. 7 through 9, the pattern data generator 121-1 may generate the pattern data PDATA. The phase shift block 123-1 may shift the phase of the clock signal CLK in response to the control signal CS received from the control signal generator 127-1. The phase of the clock signal CLK may be shifted such that the phase-shifted clock signal CLK has a rising or falling edge at one of time points C1 through C15.

The pattern data PDATA may be latched according to the clock signal CLK having a phase shift such that the phase-shifted clock signal CLK has a rising or falling edge at one of the time points C1 through C15. The comparator 129-1 may determine the write training operation to have passed or failed according to whether the latched pattern data L_PDATA is the same as the read data RDATA.

Referring to FIG. 9, when the pattern data PDATA has a value of DATA0 according to the phase-shifted clock signal CLK, and the read data RDATA has a value of DATA1 according to the read data strobe signal RDQS, the read data RDATA is the same as the latched pattern data L_PDATA. For example, when the phase-shifted clock signal CLK has a phase shift to have a rising or falling edge at one of time points C1 through C4, the read data RDATA is not the same as the latched pattern data L_PDATA and the memory controller 100 may determine the write training operation to have failed. When the phase-shifted clock signal CLK has a phase shift to have a rising or falling edge at one of time points C5 through C11, the read data RDATA is the same as the latched pattern data L_PDATA and the memory controller 100 may determine the write training operation to have passed. When the shifted clock signal CLK has a phase shift to have a rising or falling edge at one of time points C12 through C15, the read data RDATA is not the same as the latched pattern data L_PDATA and the memory controller 100 may determine the write training operation to have failed.

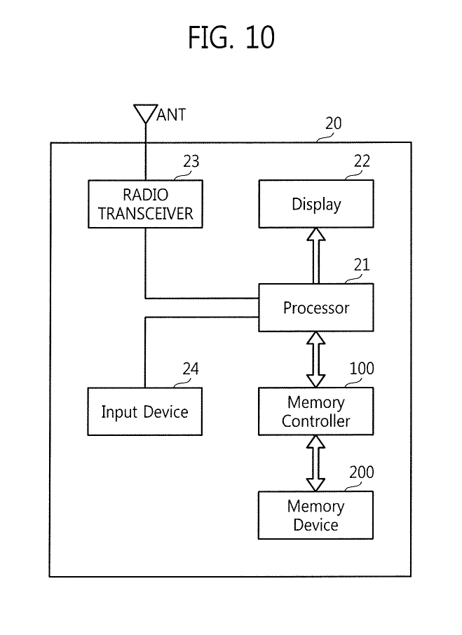

FIG. 10 is a block diagram of a data processing system 20 according to an exemplary embodiment of the present inventive concept. Referring to FIGS. 1 through 10, the data processing system 20 may be implemented as a cellular phone, a smart phone, a tablet PC, a PDA, an IoT device, an IoE device, a radio communication system, or the like.

The data processing system 20 may include the memory controller 100 and the flash memory device 200. The memory controller 100 may control data access operations, e.g., a program operation, an erase operation, a read operation, or the like, of the flash memory device 200 according to control of a processor 21.

A radio transceiver 23 may transmit or receive radio signals through an antenna ANT. The radio transceiver 23 may convert radio signals received through the antenna ANT into signals that can be processed by the processor 21. The radio transceiver 23 may convert signals output from the processor 21 into radio signals and output the radio signals to an external device through the antenna ANT.

An input device 24 enables control signals for controlling the operation of the processor 21 or data to be processed by the processor 21 to be input to the data processing system 20. The input device 24 may be implemented as a pointing device such as a touch pad or a computer mouse, a keypad, a keyboard, or the like. The processor 21 may control an operation of a display 22 to display data output from the memory controller 100, data output from the radio transceiver 23, or data output from the input device 24. The memory controller 100, which controls the operations of the flash memory device 200, may be implemented as a part of the processor 21 or as a separate chip.

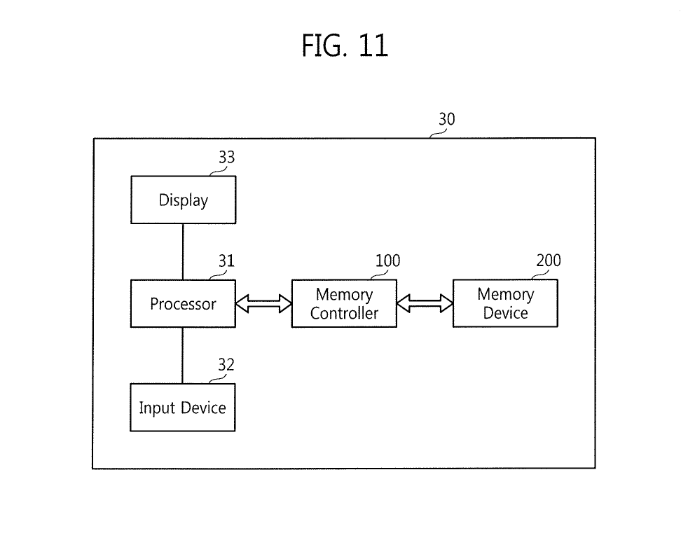

FIG. 11 is a block diagram of a data processing system 30 according to an exemplary embodiment of the present inventive concept. The data processing system 30 may be implemented as a PC, a tablet PC, a net-book, an e-reader, a PDA, a PMP, an MP3 player, an MP4 player, or the like.

The data processing system 30 includes the memory controller 100 and the flash memory device 200. A processor 31 may display data stored in the flash memory device 200 through a display 33 according to data input through an input device 32. The input device 32 may be implemented as a pointing device such as a touch pad or a computer mouse, a keypad, a keyboard, or the like.

The processor 31 may control the overall operation of the data processing system 30 and the operations of the memory controller 100. The memory controller 100, which may control the operations of the flash memory device 200, may be implemented as a part of the processor 31 or as a separate chip.

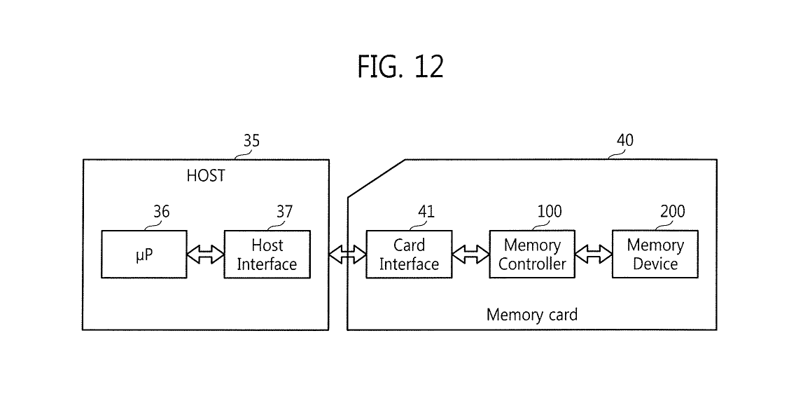

FIG. 12 is a block diagram of a data processing system 40 according to an exemplary embodiment of the present inventive concept. The data processing system 40 may be implemented as a memory card, a smart card, or the like. The data processing system 40 includes a card interface 40, the memory controller 100, and the flash memory device 200.

The memory controller 100 may control data exchange between the card interface 41 and the flash memory device 200. The card interface 41 may be an SD card interface or an MMC interface, but the present inventive concept is not restricted thereto.

The card interface 41 may interface a host 35 and the memory controller 100 for data exchange according to a protocol of the host 35. The card interface 41 may support a universal serial bus (USB) protocol and an interchip (IC)-USB protocol. Here, the card interface 41 may be understood as hardware that supports a protocol used by the host 35, software that is installed in the hardware, or a signal transmission mode.

When the data processing system 40 is connected with the host 35, such as a PC, a tablet PC, a digital camera, a digital audio player, a cellular phone, a console video game hardware, a digital set-top box, or the like, a host interface 37 of the host 35 may perform data communication with the flash memory device 200 through the card interface 41 and the memory controller 100 according to control of a microprocessor 36.

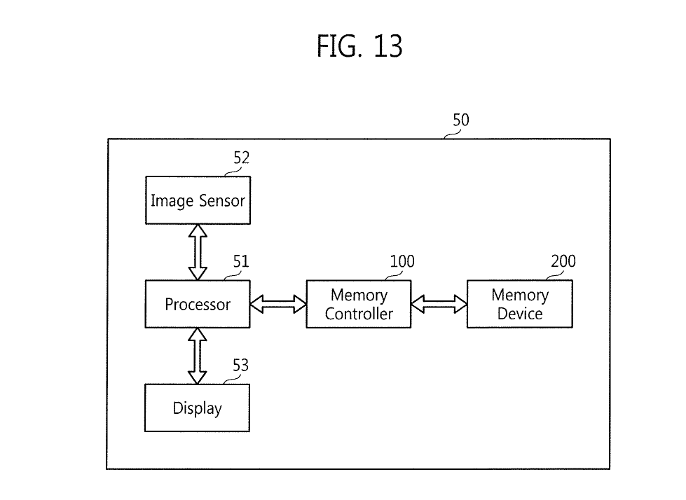

FIG. 13 is a block diagram of a data processing system 50 according to an exemplary embodiment of the present inventive concept. The data processing system 50 may be implemented as an image processor such as a digital camera, a cellular phone equipped with a digital camera, a smart phone equipped with a digital camera, a tablet PC equipped with a digital camera, or the like.

The data processing system 50 includes the flash memory device 200 and the memory controller 100 that controls data processing operations, such as a program operation, an erase operation, a read operation, or the like, of the flash memory device 200. An image sensor 52 included in the data processing system 50 converts optical images into digital signals and outputs the digital signals to a processor 51 or the memory controller 100. According to the control of the processor 51, the digital signals may be displayed through a display 53 or stored in the flash memory device 200 through the memory controller 100.

Data stored in the flash memory device 200 may be displayed through the display 53 according to the control of the processor 51 or the memory controller 100. The memory controller 100, which may control the operations of the flash memory device 200, may be implemented as a part of the processor 51 or as a separate chip.

As described above, according to an exemplary embodiment of the present inventive concept, a memory controller performs a data training operation in a flash memory device operating at a high speed, and thus, data skew that may occur between the memory controller and the flash memory device may be compensated and a wide eye margin may be achieved. In addition, the memory controller may reduce a time taken for the data training operation and may prevent interference among memory cells or data loss due to cell charge loss, and thus, the reliability of the data training operation may be increased.

While the present inventive concept has been particularly shown and described with reference to exemplary embodiments thereof, it will be understood by those of ordinary skill in the art that various changes in forms and details may be made therein without departing from the spirit and scope of the present inventive concept as defined by the following claims.

What is claimed is:

1. A memory controller for controlling a flash memory device,
wherein the memory controller generates pattern data, a program command, and a read command, transmits the program command and first data corresponding to the pattern data to the flash memory device to program the first data to the flash memory device, receives first read data corresponding to the first data, receives a first read data strobe signal, compares the first data with second data corresponding to the first read data, and performs a data training operation according to a comparison result,
wherein the first read data and the first read strobe signal are transmitted from the flash memory device in response to the read command.

2. The memory controller of claim 1, comprising:
a phase shift block configured to shift a phase of the first read data strobe signal when the data training operation is a read training operation; and
a latch block configured to latch the first read data in response to the first read data strobe signal whose phase has been shifted by the phase shift block, and to output the latched first read data as the second data.

3. The memory controller of claim 2, further comprising a comparator configured to compare the first data with the second data, and to output a pass signal of the read training operation when the first data is the same as the second data.

4. The memory controller of claim 2, further comprising:
a comparator configured to compare the first data with the second data and to output a fail signal of the read training operation when the first data is not the same as the second data; and
a processing unit configured to retransmit the read command to the flash memory device in response to the fail signal,
wherein the phase shift block receives a second read data strobe signal from the flash memory device,
wherein the latch block receives a second read data from a page buffer of the flash memory device.

5. The memory controller of claim 2, wherein the first data is transmitted to the flash memory device in synchronization with a clock signal having a first frequency,
wherein the first read data is received from the flash memory device in synchronization with the first read data strobe signal having a second frequency, and
wherein the first frequency is lower than the second frequency.

6. The memory controller of claim 1, wherein the first read data strobe signal is generated by the flash memory device.

7. The memory controller of claim 1, comprising:
a phase shift block configured to first shift a phase of a clock signal when the data training operation is a write training operation; and
a latch block configured to first latch the pattern data in response to the clock signal whose phase has been shifted by the phase shift block, and to output the first latched pattern data as the first data.

8. The memory controller of claim 7, further comprising a comparator configured to compare the first data with the second data, and to output a pass signal of the write training operation when the first data is the same as the second data.

9. The memory controller of claim 7, further comprising:
a comparator configured to compare the first data with the second data, and to output a fail signal of the write training operation when the first data is not the same as the second data,
wherein the phase shift block second shifts the phase of the clock signal in response to the fail signal, and
wherein the latch block second latches the pattern data in response to the clock signal whose phase has been second shifted by the phase shift block and outputs the second latched pattern data as the first data.

10. A memory system comprising:
a flash memory device; and
a memory controller configured to control a data training operation of the flash memory device,
wherein the memory controller generates pattern data, a program command, a read command, transmits the program command and first data corresponding to the pattern data to the flash memory device program the first data to the flash memory device, receives first read data corresponding to the first data, receives a first read data strobe signal, compares the first data with second data corresponding to the first read data, and performs the data training operation according to a comparison result,
wherein the first read data and the first read strobe signal are transmitted from the flash memory device in response to the read command.

11. The memory system of claim 10, wherein the memory controller comprises:
a phase shift block configured to shift a phase of the first read data strobe signal when the data training operation is a read training operation; and
a latch block configured to latch the first read data in response to the first read data strobe signal whose phase has been shifted by the phase shift block, and to output the latched first read data as the second data.

12. The memory system of claim 11, wherein the memory controller further comprises:
a comparator configured to compare the first data with the second data, and to output a fail signal of the read training operation when the first data is not the same as the second data; and
a processing unit configured to retransmit the read command to the flash memory device in response to the fail signal, wherein the phase shift block receives a second read data strobe signal from the flash memory device, and
wherein the latch block receives a second read data from a page buffer of the flash memory device.

13. The memory system of claim 11, wherein the first data is transmitted to the flash memory device in synchronization with a clock signal having a first frequency,
wherein the first read data is received from the flash memory device in synchronization with the first read data strobe signal having a second frequency, and
wherein the first frequency is lower than the second frequency.

14. The memory system of claim 10, wherein the memory controller comprises:
a phase shift block configured to first shift a phase of a clock signal when the data raining operation is a write training operation; and a latch block configured to first latch the pattern data in response to the clock signal whose phase has been first shifted by the phase shift block, and to output the first latched pattern data as the first data.

15. The memory system of claim 14, wherein the memory controller further comprises a comparator configured to compare the first data with the second data, and to output a fail signal with respect to the write training operation when the first data is not the same as the second data,
wherein the phase shift block second shifts the phase of the clock signal in response to the fail signal, and
wherein the latch block second latches the pattern data in response to the clock signal whose phase has been second shifted by the phase shift block and outputs the second latched pattern data as the first data.

16. A method of operating a memory system comprising:
generating, by a memory controller of the memory system, first data, a program command, and a read command,
transmitting, by the memory controller, the first data and the program command to a flash memory device of the memory system,
programming, by the flash memory device, the first data to a page buffer of the flash memory device in response to the program command,
transmitting, by the memory controller, the read command to the flash memory device,
receiving, by the memory controller, a first read data and a first read strobe signal,
generating, by the memory controller, second data by latching the first read data, and
comparing, by the memory controller, the first data with the second data.

17. The method of claim 16, further comprising:
shifting a phase of the first read data strobe signal when the memory controller is in a read training operation,
wherein the latching of the first read data is performed in response to the first read data strobe signal whose phase has been shifted.

18. The method of claim 17, further comprising determining, by the memory controller, the read training operation to have passed when the first data is the same as the second data.

19. The method of claim 17, further comprising determining, by the memory controller, the read training operation to have failed when the first data is not the same as the second data.

20. The method of claim 9, wherein the first data is transmitted to the flash memory device in synchronization with a clock signal having a first frequency,
wherein the first read data is received from the flash memory device in synchronization with the first read data strobe signal having a second frequency, and
wherein the first frequency is lower than the second frequency.
